(19) United States
(12) Patent Application Publication
(10) Pub. No.: US 2013/0280522 A1
(43) Pub. Date: Oct. 24, 2013

(54) SURFACE TREATMENT METHOD FOR DIAMOND-LIKE CARBON LAYER AND COATED ARTICLE MANUFACTURED BY THE METHOD

(71) Applicant: DA-HUA CAO, Shenzhen City (CN)

(72) Inventor: DA-HUA CAO, Shenzhen City (CN)

(21) Appl. No.: 13/655,645

(22) Filed: Oct. 19, 2012

(30) Foreign Application Priority Data
Apr. 20, 2012 (CN) 201210117519.9

(51) Int. Cl. C23C 14/06; B32B 9/04; C09D 1/00; C23C 14/35

(52) U.S. Cl. 428/336; 204/192.15; 428/446; 428/448; 428/450; 106/286.8

(57) ABSTRACT

A surface treatment method for diamond-like carbon layer include at least the following steps: a substrate is provided; a diamond-like carbon layer is formed on the substrate by ion beam assisted magnetron sputtering deposition; fluorine ions and silicone ions is doped in the diamond-like carbon layer at a temperature of about 400° C. to about 600° C. A coated article manufactured by the method is also provided.

### BACKGROUND

1. Technical Field

The present disclosure generally relates to surface treatment method for diamond-like carbon layer and a coated article manufactured by the surface treatment method.

2. Description of Related Art

Metal or non-metal elements are usually doped in diamond-like carbon (DLC) layers by magnetron sputtering deposition to enhance the hardness of the DLC layers. However, the metal or non-metal elements can increase the internal stress of the DLC layer. As a result, the doped DLC layers have reduced bond to the substrate.

Therefore, there is room for improvement within the art.

### BRIEF DESCRIPTION OF THE DRAWINGS

Many aspects of the embodiment can be better understood with reference to the following drawings. The components in the drawings are not necessarily drawn to scale, the emphasis instead being placed upon clearly illustrating the principles of the exemplary disclosure. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of a substrate coated with a DLC layer.

FIG. 2 is a cross-sectional view of an exemplary embodiment of a coated article.

FIG. 3 is a cross-sectional view of an exemplary embodiment of a magnetron sputtering deposition device.

### DETAILED DESCRIPTION

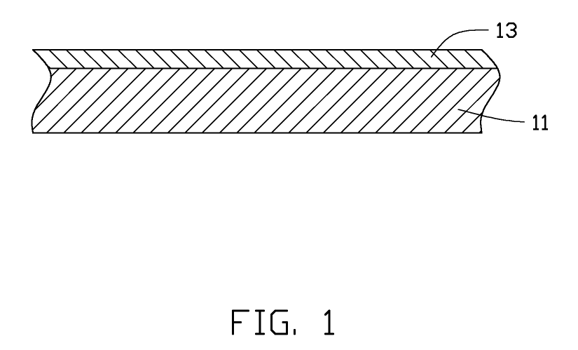

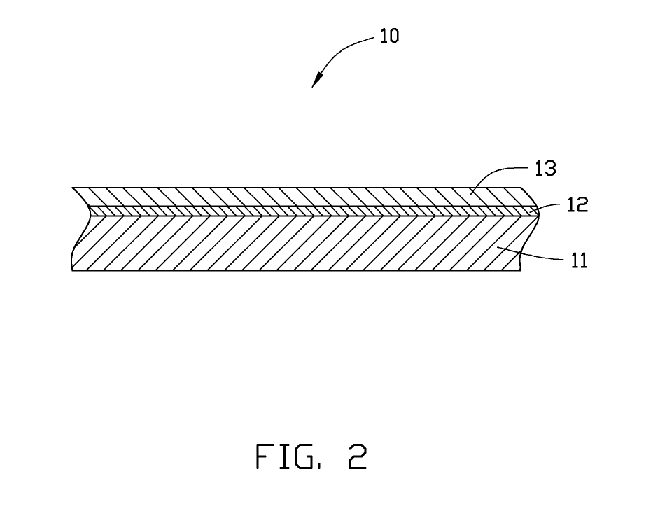

Referring to FIGS. 1 and 2, a surface treatment method for DLC layer may include at least the following steps:

A substrate 11 is provided. The substrate 11 is degreased to remove contaminants, such as grease or dirt. The substrate 11 may be made of stainless steel, high speed steel, copper, titanium alloy, or hard alloy.

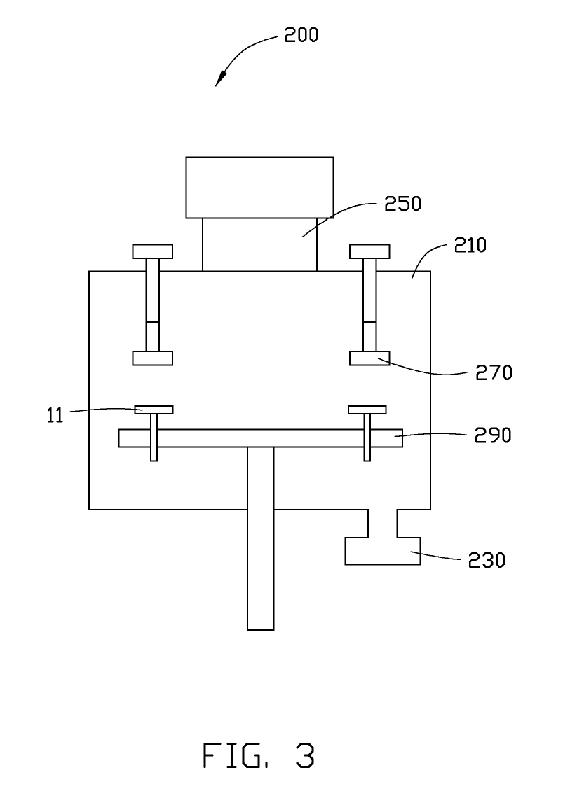

The substrate 11 is cleaned by argon (Ar) plasma. Referring to FIG. 3, a magnetron sputtering deposition device 200 is provided. The magnetron sputtering deposition device 200 may be a ion beam assisted magnetron sputtering deposition device. The device 200 includes a chamber 210, a pump 230, and an ion source 250. The pump 230 and the ion source 250 are each connected to the chamber 210. The device 200 further includes two graphite targets 270, and a rotating bracket 290 mounted in the chamber 210. The rotating bracket 290 is attached to the bottom wall of the chamber 210. The substrate 11 is retained on the rotating bracket 290. Each graphite targets 270 is mounted on the top wall of the chamber 210 corresponding to the substrate 11. The pressure inside of the chamber 210 is about 7.0×10⁻³ Pa to about 4.0×10⁻³ Pa. Argon gas is fed into the chamber 210 at a flow rate about 250 standard cubic centimeters per minute (sccm) to about 350 sccm. A bias voltage applied to the substrate 11 may be between about −800 volts (V) and about −1200 V. The argon particles strike against the surface of the substrate 11 to clean substrate 11. The bias power is about 6 kW to about 12 kW. The internal temperature of the chamber 210 is between about 180 degrees Celsius (° C.) and about 240° C. Cleaning the substrate 11 may take from about 10 minutes (min) to about 30 min.

A diamond-like carbon (DLC) layer 13 is formed by ion beam assisted magnetron sputtering deposition. The graphite targets 270 in the chamber 210 are applied a power between about 10 kW to about 18 kW. Argon and carbon containing gas are first ionized by ion source 250 and then fed into the chamber 210. Argon may have a flow rate of about 150 sccm to about 200 sccm. Carbon containing gas may have a flow rate of about 150 sccm to about 200 sccm. The carbon containing gas may be methane, acetylene, ethanol, or acetone. The ion source 250 produces ion beams having energy of about 5 keV to about 30 keV and from about 30 mA to about 50 mA. A bias voltage applied to the substrate 11 may be between about −50 V and about −200 V. Depositing the DLC layer 13 may take about 180 minutes to 240 minutes. The thickness of the DLC layer 13 is about 2 μm to about 3 μm. After deposition of the DLC layer 13, the power applied to the graphite targets 270 is turned off.

The DLC layer 13 is doped with fluorine ions and silicone ions. The pressure inside of the chamber 210 is about 0.5 Pa to about 2.5 Pa. The internal temperature of the chamber 210 is about 400° C. to about 600° C. Argon, silane gas and carbon tetrafluoride (CF₄) are ionized by ion source 250, and then fed into the chamber 210. The argon may have a flow rate of about 200 sccm to about 300 sccm, the silane may have a flow rate of about 100 sccm to about 200 sccm, the carbon tetrafluoride may have a flow rate of about 100 sccm to about 200 sccm. The volume ratio of argon, silane, and carbon tetrafluoride is about 2:1:1 to about 3:2:2. The ion source 250 produces ion beams having energy of about 5 keV to about 30 keV and from about 20 mA to about 50 mA. The doping process may take about 1.6 hours to 2.5 hours. After the doping process, the silane and carbon tetrafluoride are stopped from being fed into the chamber 210.

During the doping process, fluorine and silicone ions penetrate into the DLC layer 13 and the substrate 11 at the region adjacent to the DLC layer 13. At the same time, a diffusing layer 12 is formed between the substrate 11 and the DLC layer 13 by a solid phase diffusion occurring between the substrate 11 and the DLC layer 13. The diffusing layer 12 contains silicon carbide, iron carbide, silicon-iron solid solution, and fluorine-iron solid solution. The diffusing layer 12 has a thickness of about 1 μm to about 2 μm.

The substrate 11 is cooled. Argon is fed into the chamber 210 and keeps the pressure inside of the chamber 210 at about 1.0×10⁵ Pa to about 1.0×10⁵ Pa. The internal temperature of the chamber 210 is decreased from about 400° C.-600° C. to about 60° C.-70° C. in about 20 min to about 40 min.

The doping process enhances the hardness of the DLC layer 13. The diffusing layer 12 improves the bond between the substrate 11 and the DLC layer 13. Additionally, fluorine (F) element and silicone (Si) element doped in the DLC layer 13 decreases the surface energy of the DLC layer 13.

A coated article 10 manufactured by the exemplary method includes a substrate 11, a DLC layer 13 formed on the substrate 11, and a diffusing layer 12 formed between the substrate 11 and the DLC layer 13.

The article 10 may be a housing of a mobile phone, a notebook computer, a portable music player, or a digital camera.

The substrate 11 may be made of stainless steel, high speed steel, copper, titanium alloy, or hard alloy.

The diffusing layer 12 contains silicon carbide, iron carbide, silicon-iron solid solution, and fluorine-iron solid solution. The diffusing layer 12 has a thickness of about 1 μm to about 2 μm.

The DLC layer 13 has a thickness of about 2 μm to about 2.5 μm. The DLC layer 13 contains F element, Si element and hydrogen (H) element. In the DLC layer 13, the totally mass percentage of the Si element, the F element and the H element is about 1% to about 3%.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A surface treatment method for diamond-like carbon layer, comprising:
providing a substrate;
depositing a diamond-like carbon layer on the substrate by magnetron sputtering deposition;
doping fluorine ions and silicone ions in the diamond-like carbon layer at a temperature of about 400° C. to about 600° C.

2. The surface treatment method of claim 1, wherein the substrate is made of stainless steel, high speed steel, copper, titanium alloy, or hard alloy.

3. The surface treatment method of claim 1, wherein during depositing of the diamond-like carbon layer, the substrate is mounted in a chamber of a magnetron sputtering deposition device, the device comprising graphite targets and a ion source; the graphite targets are applied a power between about 10 kW to about 18 kW; argon and carbon containing gases are first ionized by the ion source, and then fed into the chamber, the argon has a flow rate of about 150 sccm to about 200 sccm, the carbon containing gas has a flow rate of about 150 sccm to about 200 sccm; the ion source produces ion beams having energy of about 5 keV to about 30 keV and from about 30 mA to about 50 mA, a bias voltage applied to the substrate is between about −50 V and about −200 V, depositing the DLC layer takes about 180 minutes to 240 minutes.

4. The surface treatment method of claim 3, wherein the carbon containing gas is methane, acetylene, ethanol, or acetone.

5. The surface treatment method of claim 3, wherein the thickness of the DLC layer is about 2 μm to about 3 μm.

6. The surface treatment method of claim 3, wherein during the doping process, the internal temperature of the chamber is about 400° C. to about 600° C.; argon, silane, and carbon tetrafluoride are ionized by ion source, and then fed into the chamber; the argon has a flow rate of about 200 sccm to about 300 sccm, the silane has a flow rate of about 100 sccm to about 200 sccm, the carbon tetrafluoride has a flow rate of about 100 sccm to about 200 sccm; the ion source produces ion beams having energy of about 5 keV to about 30 keV and from about 20 mA to about 50 mA, the doping process lasts for about 1.6 hours to 2.5 hours.

7. The surface treatment method of claim 6, wherein the volume ratio of argon, silane, and carbon tetrafluoride is about 2:1:1 to about 3:2:2.

8. The surface treatment method of claim 6, further comprising a step of cooling the substrate after the doping process, during the cooling process, argon is fed into the chamber and keeps the pressure inside of the chamber at about 1.0×10⁵ Pa to about 1.0×10⁵ Pa, the internal temperature of the chamber is decreased from about 400° C.-600° C. to about 60° C.-70° C. in about 20 min to about 40 min.

9. A coated article, comprising:
a substrate; and
a diamond-like carbon layer formed on the substrate, the diamond-like carbon comprising fluorine element and silicon element.

10. The coated article of claim 9, wherein the DLC layer contains silicon element, fluorine element and hydrogen element, and the total mass percentage of the silicon element, fluorine element and hydrogen element is about 1% to about 3%.

11. The coated article of claim 9, wherein the DLC layer has a thickness of about 2 lam to about 3 μm.

12. The coated article of claim 9, wherein the coated article further comprising a diffusing layer formed between the substrate and the DLC layer.

13. The coated article of claim 12, wherein the diffusing layer contains silicon carbide, iron carbide, silicon-iron solid solution, and fluorine-iron solid solution.

14. The coated article of claim 12, wherein the diffusing layer has a thickness of about 1 μm to about 2 μm.

15. The coated article of claim 9, wherein the substrate is made of stainless steel, high speed steel, copper, titanium alloy, or hard alloy.
